(19) United States
(12) Patent Application Publication
(10) Pub. No.: US 2026/0020445 A1
(43) Pub. Date: Jan. 15, 2026

(54) DISPLAY PANEL, DISPLAY DEVICE, AND PREPARATION METHOD FOR DISPLAY PANEL

(71) Applicants: Hefei Visionox Technology Co., Ltd., Hefei (CN); Visionox Technology Inc., Kunshan (CN)

(72) Inventors: Zengqiang XIA, Hefei (CN); Manli CHEN, Kunshan (CN); Tian WANG, Hefei (CN); Yafei SUN, Kunshan (CN); Peng QIN, Kunshan (CN)

(73) Assignees: Hefei Visionox Technology Co., Ltd., Hefei (CN); Visionox Technology Inc., Kunshan (CN)

(21) Appl. No.: 19/266,107

(22) Filed: Jul. 10, 2025

(30) Foreign Application Priority Data
Jul. 15, 2024 (CN) 202410949436.9
Sep. 14, 2024 (CN) 202411296813.X

(51) Int. Cl. H10K 59/122; H10H 29/01; H10H 29/37; H10H 29/80; H10K 59/12; H10K 59/80

(52) U.S. Cl. CPC H10K 59/122; H10H 29/012; H10H 29/37; H10H 29/8321; H10K 59/1201; H10K 59/80515; H10K 59/80521

(57) ABSTRACT

The present application discloses a display panel including a substrate, a pixel defining layer, an isolation structure and a light-emitting unit, the pixel defining layer is disposed on one side of the substrate and includes a pixel defining portion and a pixel opening enclosed by the pixel defining portion; the isolation structure is disposed on one side of the substrate and encloses an isolation opening in communication with the pixel opening; and the light-emitting unit is disposed in the pixel opening and includes a plurality of sub-layers, at least one sub-layer includes a first portion and a second portion on a side of the first portion close to the isolation structure, a thickness of the second portion gradually decreases in a direction close to the isolation structure, and an orthographic projection of the second portion on the substrate partially overlaps an orthographic projection of the pixel opening on the substrate.

### CROSS REFERENCE

The present disclosure claims priorities to Chinese Patent Application No. 202410949436.9 titled “DISPLAY PANEL, DISPLAY DEVICE, AND PREPARATION METHOD FOR DISPLAY PANEL” filed on Jul. 15, 2024, and to Chinese Patent Application No. 202411296813.X titled “DISPLAY PANEL, PREPARATION METHOD, AND DISPLAY DEVICE” filed on Sep. 14, 2024 which are incorporated herein by reference in their entireties.

### FIELD

The present application relates to the field of displays, and in particular to a display panel and a display device.

### BACKGROUND

Organic light-emitting diodes (OLEDs) and flat panel display devices based on technologies such as light-emitting diodes (LEDs) have been widely applied to various consumer electronics such as mobile phones, televisions, notebook computers and desktop computers and predominate in display devices thanks to their advantages such as high image quality, energy efficiency, slim design and a wide range of applications.

However, the usage performance of conventional OLED display products needs to be improved.

### SUMMARY

An objective of the present application is to provide a display panel and a display device, which can improve the performance of the display panel.

A first aspect of the present application provides a display panel including a substrate, a pixel defining layer, an isolation structure and a light-emitting unit, where the pixel defining layer is disposed on one side of the substrate, and includes a pixel defining portion and a pixel opening enclosed by the pixel defining portion; the isolation structure is disposed on one side of the substrate and encloses an isolation opening, the isolation opening being in communication with the pixel opening; and the light-emitting unit is disposed in the pixel opening and includes a plurality of sub-layers, at least one sub-layer includes a first portion and a second portion on a side of the first portion close to the isolation structure, a thickness of the second portion gradually decreases in a direction close to the isolation structure, and an orthographic projection of the second portion on the substrate partially overlaps an orthographic projection of the pixel opening on the substrate.

In some embodiments, the plurality of sub-layers include a light-emitting functional layer and a first electrode stacked on a side of the light-emitting functional layer facing away from the substrate, the first electrode including a first portion and a second portion;
in one embodiment, the plurality of sub-layers further include a first carrier layer between the light-emitting functional layer and the first electrode, the first carrier layer including the first portion and the second portion;
in one embodiment, the light-emitting functional layer includes the first portion and the second portion; and
in one embodiment, the plurality of sub-layers further include a second electrode and a second carrier layer between the second electrode and the light-emitting functional layer, the second carrier layer including the first portion and the second portion.

In some embodiments, the isolation structure includes a first isolation segment and a second isolation segment located on a peripheral side of the isolation opening, the first electrode being connected to the first isolation segment,
where the first electrode is connected to the second isolation segment, or the first electrode is spaced apart from the second isolation segment.

In some embodiments, the first electrode is spaced apart from the second isolation segment, and a distance from a side of the first isolation segment facing the isolation opening to the pixel opening is less than a distance from a side of the second isolation segment facing the corresponding isolation opening to the corresponding pixel opening.

In some embodiments, the isolation structure includes a first isolation portion and a second isolation portion stacked in a direction away from the substrate, and an orthographic projection of the first isolation portion on the substrate is within an orthographic projection of the second isolation portion on the substrate; and
in one embodiment, the isolation structure further includes a third isolation portion, the third isolation portion being stacked on a side of the first isolation portion facing the substrate.

In some embodiments, a thickness reduction line is formed between the first portion and the second portion, a side of the second isolation portion facing the isolation opening forms an evaporation edge, a virtual connection plane is connected between the thickness reduction line and the evaporation edge, and an included angle θ₁ between the virtual connection plane and a thickness direction of the substrate satisfies: 30°≤θ₁≤70°;
in one embodiment, a distance from the evaporation edge to the side of the pixel defining portion facing away from the substrate is a first distance, the first distance H1 satisfying: 0.5 microns≤H1≤1.5 microns.

In some embodiments, the plurality of sub-layers include a light-emitting functional layer and a first electrode stacked on a side of the light-emitting functional layer facing away from the substrate, the first electrode and the light-emitting functional layer each include the first portion and the second portion, and the included angle of the first electrode is greater than or equal to the included angle of the light-emitting functional layer;
in one embodiment, the included angle θ₂ of the first electrode satisfies: 55°≤θ₂≤ 70°; and
in one embodiment, the included angle 03 of the light-emitting functional layer satisfies: 30°≤θ₃≤55°.

In some embodiments, a thickness reduction line is formed between the first portion and the second portion, a distance from the thickness reduction line to a center of the corresponding pixel opening is a second distance, the plurality of light-emitting units include a first light-emitting unit, a second light-emitting unit and a third light- emitting unit, the second distance of the first light-emitting unit is greater than the second distance of the second light-emitting unit, and the second distance of the second light-emitting unit is greater than the second distance of the third light-emitting unit;
in one embodiment, the isolation structure includes a first isolation portion and a second isolation portion stacked in a direction away from the substrate, an orthographic projection of the first isolation portion on the substrate is within an orthographic projection of the second isolation portion on the substrate, the second isolation portion includes a protruding sub-portion protruding in a direction close to the isolation opening with respect to the first isolation portion, a protruding width of the protruding sub-portion corresponding to the first light-emitting unit is smaller than a protruding width of the protruding sub-portion corresponding to the second light-emitting unit, and the protruding width of the protruding sub-portion corresponding to the second light-emitting unit is smaller than a protruding width of the protruding sub-portion corresponding to the third light-emitting unit;
in one embodiment, a side of the second isolation portion facing the isolation opening forms an evaporation edge, a virtual connection plane is connected between the thickness reduction line and the evaporation edge, and an included angle θ₁ between the virtual connection plane and a thickness direction of the substrate satisfies: 30°≤θ₁≤70°,
where the included angle corresponding to the first light-emitting unit is less than the included angle corresponding to the second light-emitting unit, and the included angle corresponding to the second light-emitting unit is less than the included angle corresponding to the third light-emitting unit.

In some embodiments, the side of the pixel defining layer close to the pixel opening has a ramp having a ramp angle 0, and the light-emitting functional layer includes a uniform area and a thinned area, the uniform area being located in the middle of the first electrode, and the thinned area being located between an edge of the uniform area and an edge of the pixel defining layer; a length L of the thinned area satisfies a relation: L≤H (tanα−tan(π/2−θ)), where a is the evaporation angle, α and θ are acute angles, and H is the thickness of the pixel defining layer; L has the same unit as H; and
the length L satisfies at least one of the following three: H≤15000 angstroms; α≤70°; and θ≤35°.

In one embodiment, the pixel defining layer has a multi-layer structure.

In a second aspect, the present application provides a display device, including a display panel according to any of the above embodiments.

In a third aspect, the present application provides a method for preparing a display panel. The method includes:
forming a pixel defining layer on one side of a substrate, the pixel defining layer including a pixel defining portion and a pixel opening enclosed by the pixel defining portion;
forming an isolation structure on one side of the substrate, the isolation structure enclosing an isolation opening in communication with the pixel opening; and
forming a light-emitting unit in the pixel opening, where the light-emitting unit includes a plurality of sub-layers, at least one sub-layer includes a first portion and a second portion on a side of the first portion close to the isolation structure, a thickness of the second portion gradually decreases in a direction close to the isolation structure, and an orthographic projection of the second portion on the substrate partially overlaps an orthographic projection of the pixel opening on the substrate.

Embodiments of the present application provide a display panel, a display device, and a method for preparing a display panel, the display panel including a substrate, a pixel defining layer, an isolation structure and a light-emitting unit, where the pixel defining layer is disposed on one side of the substrate and includes a pixel defining portion and a pixel opening enclosed by the pixel defining portion, the isolation structure is disposed on one side of the substrate and encloses an isolation opening in communication with the pixel opening, the light-emitting unit is disposed in the pixel opening and includes a plurality of sub-layers, at least one sub-layer includes a first portion and a second portion on a side of the first portion close to the isolation opening, a thickness of the second portion gradually decreases in a direction close to the isolation structure, an orthographic projection of the second portion on the substrate partially overlaps an orthographic projection of the pixel opening on the substrate, that is, the first portion and part of the second portion of the sub-layer are located in the pixel opening, and compared with the provision of a misalignment of an orthographic projection of the second portion on the substrate with an orthographic projection of the pixel opening on the substrate, the space occupied by the light-emitting unit outside the pixel opening can be reduced, and the width dimension of the pixel defining portion in the direction parallel to the substrate can be correspondingly reduced, thereby reducing the pixel pitch, and thus facilitating an increase in the PPI of the display panel and improving the usage performance of the display panel.

### BRIEF DESCRIPTION OF THE DRAWINGS

In order to describe the embodiments of the present application more clearly, the drawings required for illustration of the embodiments of the present application will be briefly introduced below. Apparently, the drawings as described below are only for some of the embodiments of the present application.

FIG. 1 is a schematic cross-sectional view of a display panel according to some embodiments of the present application;

FIG. 2 is a further schematic cross-sectional view of a display panel according to some embodiments of the present application;

FIG. 3 is a schematic cross-sectional view of a display panel according to some other embodiments of the present application;

FIG. 4 is a schematic cross-sectional view of a display panel according to still other embodiments of the present application;

FIG. 5 is a schematic cross-sectional view of a display panel according to yet other embodiments of the present application;

FIG. 6 is a further schematic cross-sectional view of a display panel according to yet other embodiments of the present application;

FIG. 7 is a schematic cross-sectional view of a display panel according to still some embodiments of the present application; and

FIG. 8 is a flowchart of a method for preparing a display panel according to some embodiments of the present application.

FIG. 9 is a schematic cross-sectional view of the length of the thinned area in the pixel defining layer of the display panel according to some embodiments of the present application.

Reference numerals in the drawings are as follows:

Substrate 10; Display panel 100; Pixel defining layer 20; Pixel defining portion 21; Pixel opening 22; Isolation structure 30; Isolation opening 31; First isolation segment 32; Second isolation segment 33; First isolation portion 34; Second isolation portion 35; Protruding sub-portion 351; Third isolation portion 36; Light-emitting unit 40; Sub-layer 41; First portion 411; Second portion 412; Light-emitting functional layer 42; First electrode 43; Second electrode 44; First light-emitting unit 45; Second light-emitting unit 46; Third light-emitting unit 47; Thickness reduction line P1; Evaporation edge P2; Virtual connection plane P3.

### DETAILED DESCRIPTION OF THE EMBODIMENTS

The embodiments of the present application are further described in detail below with reference to the accompanying drawings and embodiments. The following detailed description of the embodiments and the accompanying drawings are used to illustrate the principle of the present application in an exemplary manner, but shall not be used to limit the scope of the present application. That is, the present application is not limited to the described embodiments.

In the description of the present application, it should be noted that “a plurality of” means two or more, unless otherwise specified. The orientation or position relationship indicated by the terms “upper”, “lower”, “left”, “right”, “inner”, “outer”, etc. is merely for the convenience of describing the present application and simplifying the description, rather than indicating or implying that a device or element referred to must have a particular orientation or be constructed and operated in a particular orientation, and therefore should not be construed as limiting the present application. In addition, the terms “first”, “second” and “third” are for descriptive purposes only and should not be construed as indicating or implying relative importance. The term “perpendicular” does not mean being perpendicular in the strict sense, but within an allowable range of tolerance. The term “parallel” does not mean being parallel in the strict sense, but within an allowable range of tolerance.

The phrase “embodiment” mentioned in the present application means that the specific features, structures and characteristics described with reference to the embodiment may be encompassed in at least one embodiment of the present application. This phrase in various places in the specification does not necessarily refer to the same embodiment or an independent or another embodiment exclusive of other embodiments.

The orientation terms in the following description all indicate directions shown in the accompanying drawings, and do not limit the specific structure in the present application. In the description of the present application, it should be noted that, the terms “mount”, “connected”, or “connect” should be interpreted in a broad sense unless explicitly defined and limited otherwise. For example, they may be a fixed connection, a detachable connection, or an integral connection; or may mean a direct connection, or an indirect connection by means of an intermediate medium. The specific meanings of the terms mentioned above in the present application may be construed according to specific circumstances.

An embodiment of the present application provides a display panel. The display panel may be an organic light-emitting diode (OLED) display panel, or another type of display panel, such as a micro light-emitting diode (Micro-LED) display panel or a quantum dot light-emitting diode (QLED) display panel.

In some display panels, an isolation structure with isolation openings is provided and light-emitting devices of different colors can be formed in different isolation openings by first full-layer evaporation and then etching. Among others, patent applications PCT/CN 2023/134518, 202310759370.2, 202310740412.8, 202310707209.0, and 202311346196.5 describe related solutions for an isolation structure, the contents of which are incorporated herein by reference.

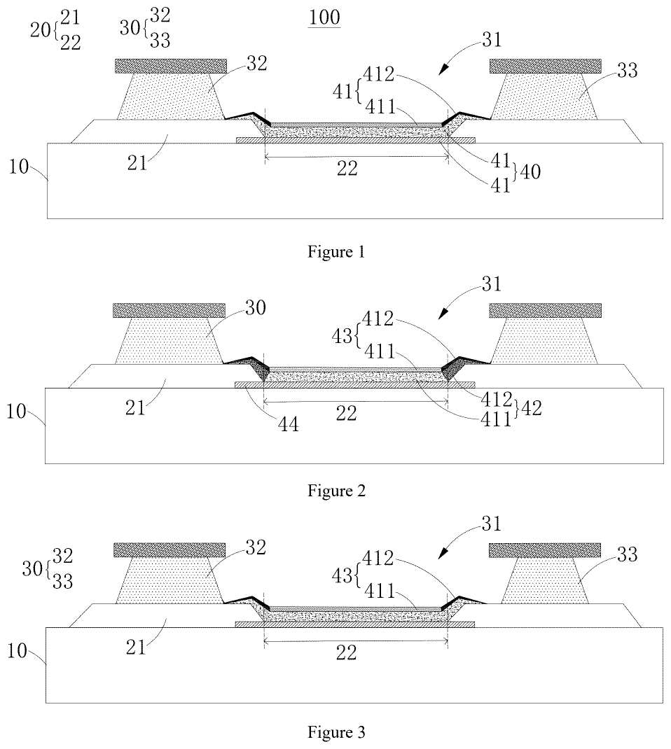

Referring to FIG. 1, a first aspect of the present application provides a display panel 100 including a substrate 10, a pixel defining layer 20, an isolation structure 30 and a light-emitting unit 40, where the pixel defining layer 20 is disposed on one side of the substrate 10, and includes a pixel defining portion 21 and a pixel opening 22 enclosed by the pixel defining portion 21; an isolation structure 30 is disposed on one side of the substrate 10 and encloses an isolation opening 31, the isolation opening 31 being in communication with the pixel opening 22; and the light-emitting unit 40 is disposed in the pixel opening 22 and includes a plurality of sub-layers 41, at least one sub-layer 41 includes a first portion 411 and a second portion 412 on a side of the first portion 411 close to the isolation structure 30, a thickness of the second portion 412 gradually decreases in a direction close to the isolation structure 30, and an orthographic projection of the second portion 412 on the substrate 10 partially overlaps an orthographic projection of the pixel opening 22 on the substrate 10.

Specifically, the substrate 10 includes a substrate and a drive circuit layer disposed on the substrate. The substrate may be a rigid substrate made of glass, plastic, or another material, or a flexible substrate made of polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), cellulose acetate propionate (CAP), or another material. A drive circuit for controlling a light-emitting unit 40 to emit light is disposed in the drive circuit layer. The drive circuit layer is generally composed of inorganic film layers such as a metal layer, a semiconductor layer (active layer), and an insulation layer. The drive circuit for controlling the light-emitting unit 40 to emit light may be formed by patterning these inorganic film layers, and there may be various embodiments of the specific circuit structure of the drive circuit, which will not be described in detail herein.

The pixel defining layer 20 is disposed on one side of the substrate 10, and includes a pixel defining portion 21 and a pixel opening 22 enclosed by the pixel defining portion 21, and the light-emitting unit 40 is disposed in the pixel opening 22, and light-emitting display of the display panel 100 can be realized; in addition, the number of the light-emitting units 40 and the pixel openings 22 may be plural, respectively, and the plurality of light-emitting units 40 are disposed one-to-one in the plurality of pixel openings 22, and carrier crosstalk in each light-emitting unit 40 may be reduced, thereby improving the display effect of the display panel 100. The isolation structure 30 is disposed on one side of the substrate 10, and encloses an isolation opening 31 in communication with the pixel opening 22, to reduce the blocking of the isolation structure 30 from the pixel opening 22, guaranteeing a light-emitting effect of the light-emitting unit 40, and a light-emitting material may be separated by the isolation structure 30 to form the light-emitting unit 40, and the light-emitting unit 40 is located in the isolation opening 31, and costs can be saved by eliminating the need for a mask to prepare the light-emitting unit 40.

The light-emitting unit 40 may include a plurality of sub-layers 41, the plurality of sub-layers 41 being stacked in succession in a thickness direction of the substrate 10, where at least one of the plurality of sub-layers 41 includes a first portion 411 and a second portion 412, the second portion 412 is located on a side of the first portion 411 close to the isolation structure 30, i.e., the first portion 411 is arranged near the center, the second portion 412 is arranged near an edge, and the second portion 412 may be arranged around a peripheral side of the first portion 411. It will be appreciated that, subject to the process of preparing the light-emitting unit 40, a thickness of the first portion 411 may be disposed substantially uniformly, and a thickness of the second portion 412 gradually decreases in a direction close to the isolation structure 30. That is, the second portion 412 is gradually thinned in the direction close to the isolation structure 30, and in the related art, the second portion 412 is typically located on a side of the pixel defining portion 21 facing away from the substrate 10, that is, located outside the pixel opening 22, thereby occupying a larger space outside the pixel opening 22, and a width dimension of the pixel defining portion 21 in a direction parallel to the substrate 10 is larger, and a spacing between two adjacent pixels is larger, thus it is difficult to meet the high PPI requirements of the display panel 100.

Thus, in an embodiment of the present application, by providing the orthographic projection of the second portion 412 on the substrate 10 to partially overlap the orthographic projection of the pixel opening 22 on the substrate 10, i.e., the first portion 411 and part of the second portion 412 of the sub-layer 41 are located in the pixel opening 22, and compared with providing the orthographic projection of the second portion 412 on the substrate 10 to misalign with the orthographic projection of the pixel opening 22 on the substrate 10, the space occupancy of the light-emitting unit 40 outside the pixel opening 22 can be reduced and the width dimension of the pixel defining portion 21 in the direction parallel to the substrate 10 can be correspondingly reduced, in turn, a pixel pitch is reduced, which is conducive to increasing the PPI of the display panel 100 and improving the usage performance of the display panel 100.

Referring to FIG. 2, in some embodiments, the plurality of sub-layers 41 include a light-emitting functional layer 42 and a first electrode 43 stacked on a side of the light-emitting functional layer 42 facing away from the substrate 10, the first electrode 43 including a first portion 411 and a second portion 412.

In these embodiments, the first electrode 43 includes a first portion 411 and a second portion 412, i.e., an orthographic projection of the second portion 412 of the first electrode 43 on the substrate 10 partially overlaps an orthographic projection of the pixel opening 22 on the substrate 10, and the first portion 411 and part of the second portion 412 of the first electrode 43 are located in the pixel opening 22, it is thus possible to reduce the space occupied by the first electrode 43 outside the pixel opening 22, which is advantageous to increase the PPI of the display panel 100.

In one embodiment, the plurality of sub-layers 41 further includes a first carrier layer between the light-emitting functional layer 42 and the first electrode 43, the first carrier layer including a first portion 411 and a second portion 412, i.e., an orthographic projection of the second portion 412 of the first carrier layer on the substrate 10 partially overlaps an orthographic projection of the pixel opening 22 on the substrate 10, and the first portion 411 and part of the second portion 412 of the first carrier layer are located in the pixel opening 22, thereby reducing the space occupied by the first carrier layer outside the pixel opening 22, and further satisfying the high PPI requirements of the display panel 100.

With continued reference to FIG. 2, in one embodiment, the light-emitting functional layer 42 includes a first portion 411 and a second portion 412, i.e., an orthographic projection of the second portion 412 of the light-emitting functional layer 42 on the substrate 10 partially overlaps an orthographic projection of the pixel opening 22 on the substrate 10, and the first portion 411 and part of the second portion 412 of the light-emitting functional layer 42 are located in the pixel opening 22, thereby reducing the space occupied by the light-emitting functional layer 42 outside the pixel opening 22, and further satisfying the high PPI requirements of the display panel 100.

In one embodiment, the plurality of sub-layers 41 further include a second electrode 44 and a second carrier layer between the second electrode 44 and the light-emitting functional layer 42, the second carrier layer including a first portion 411 and a second portion 412, i.e., an orthographic projection of the second portion 412 of the second carrier layer on the substrate 10 partially overlaps an orthographic projection of the pixel opening 22 on the substrate 10, the first portion 411 and part of the second portion 412 of the second carrier layer are located in the pixel opening 22, thereby reducing the space occupied by the second carrier layer outside the pixel opening 22, and further satisfying the high PPI requirements of the display panel 100.

It should be noted that, in the present application, one of the first electrode 43 and the second electrode 44 may serve as an anode of the light-emitting unit 40 and the other as a cathode of the light-emitting unit 40, and the embodiment of the present application is exemplified by taking the first electrode 43 as the cathode of the light-emitting unit 40 and the second electrode 44 as the anode of the light-emitting unit 40. The first carrier layer and the second carrier layer may be formed from a stack of a plurality of film layers. Exemplarily, the first carrier layer may include an electron injection layer (EIL) and an electron transport layer (ETL) that are stacked, and the second carrier layer may include a hole injection layer (HIL) and a hole transport layer (HTL) that are stacked.

Referring to FIGS. 1 and 3, in some embodiments, the isolation structure 30 includes a first isolation segment 32 and a second isolation segment 33 located on a peripheral side of the isolation opening 31, the first electrode 43 being connected to the first isolation segment 32, where the first electrode 43 is connected to the second isolation segment 33, or the first electrode 43 is spaced apart from the second isolation segment 33.

Specifically, the isolation structure 30 may be arranged around the peripheral side of the isolation opening 31, the isolation structure 30 includes a first isolation segment 32 and a second isolation segment 33, and the first isolation segment 32 and the second isolation segment 33 are respectively connected end-to-end; or the number of the first isolation segments 32 and the second isolation segments 33 may be plural, respectively, and the plurality of first isolation segments 32 and the plurality of second isolation segments 33 are alternately arranged along the peripheral side of the isolation opening 31, which is not limited in this embodiment.

In these embodiments, the first electrode 43 is connected to the first isolation segment 32 and the first electrodes 43 of the plurality of light-emitting units 40 can be electrically connected through the isolation structure 30 to form a continuous electrode to ensure that the light-emitting units 40 emit normal light. The first electrode 43 is connected to the second isolation segment 33, and a contact area of the first electrode 43 with the isolation structure 30 can be increased and the impedance between the two can be reduced. In one embodiment, the first electrode 43 is spaced apart from the second isolation segment 33, and the width of the second isolation segment 33 can be reduced to a certain extent, which is conducive to meeting the high PPI requirements of the display panel 100.

In some embodiments, the first electrode 43 is spaced apart from the second isolation segment 33, and a distance from a side of the first isolation segment 32 facing the isolation opening 31 to the pixel opening 22 is less than a distance from a side of the second isolation segment 33 facing the corresponding isolation opening 31 to the corresponding pixel opening 22, and the width of the second isolation segment 33 is less than the width of the first isolation segment 32, which is advantageous to meet the high PPI requirements of the display panel 100.

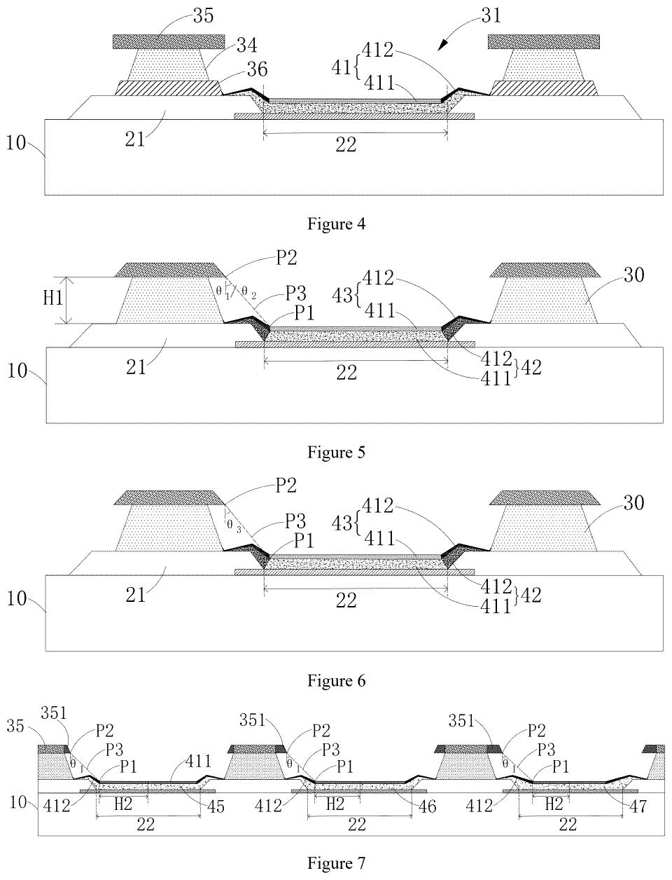

Referring to FIG. 4, in some embodiments, the isolation structure 30 includes a first isolation portion 34 and a second isolation portion 35 stacked in a direction away from the substrate 10, where an orthographic projection of the first isolation portion 34 on the substrate 10 is within an orthographic projection of the second isolation portion 35 on the substrate 10.

In these embodiments, the second isolation portion 35 is disposed on a side of the first isolation portion 34 facing away from the substrate 10, and the orthographic projection of the first isolation portion 34 on the substrate 10 is within the orthographic projection of the second isolation portion 35 on the substrate 10, thereby ensuring that the second isolation portion 35 can separate the light-emitting material to form the light-emitting unit 40, and the light-emitting unit 40 is located in the isolation opening 31, without the need for a mask to prepare the light-emitting unit 40, in order to save on costs.

With continued reference to FIG. 4, in one embodiment, the isolation structure 30 further includes a third isolation portion 36, the third isolation portion 36 being stacked on the side of the first isolation portion 34 facing the substrate 10. It is thus possible to increase the height of the isolation structure 30, which is equivalent to enabling the isolation opening 31 to have a large height drop. Since the height drop at the isolation opening 31 is large when the light-emitting unit 40 is prepared, the light-emitting material is easier to break off at the isolation structure 30, thereby reducing the preparation difficulty of the light-emitting unit 40.

Referring to FIG. 5, in some embodiments, a thickness reduction line P1 is formed between the first portion 411 and the second portion 412, a side of the second isolation portion 35 facing the isolation opening 31 forms an evaporation edge P2, a virtual connection plane P3 is connected between the thickness reduction line P1 and the evaporation edge P2, and an included angle θ₁ between the virtual connection plane P3 and a thickness direction of the substrate 10 satisfies: 30°≤θ₁≤70°.

Specifically, the thickness reduction line P1, i.e., a boundary line of the first portion 411 and the second portion 412, including the thickness of the sub-layer 41 of the first portion 411 and the second portion 412, decreases gradually from the thickness reduction line P1 in a direction close to the isolation structure 30. In the process of preparing the light-emitting unit 40, the second isolation portion 35 may act as a mask for separating the light-emitting material and the light-emitting material falls into the pixel opening 22 to form the light-emitting unit 40, and therefore, an edge of the side of the second isolation portion 35 facing the isolation opening 31 is the evaporation edge P2. It should be noted that the second isolation portion 35 may include a first surface facing the substrate 10 and a second surface facing away from the substrate 10; and when an orthographic projection of the first surface on the substrate 10 is within an orthographic projection of the second surface on the substrate 10, the evaporation edge P2 may be an edge of the second surface near the isolation opening 31, when the orthographic projection of the second surface on the substrate 10 is within the orthographic projection of the first surface on the substrate 10, the evaporation edge P2 may be the edge of the first surface near the isolation opening 31.

In these embodiments, a virtual connection plane P3 is connected between the thickness reduction line P1 and the evaporation edge P2; and by rationally setting the included angle between the virtual connection plane P3 and the thickness direction of the substrate 10, i.e., by rationally setting the evaporation angle of the light-emitting unit 40, in the case that a certain distance is provided from the evaporation edge P2 to the side of the pixel defining portion 21 facing away from the substrate 10, the orthogonal projection of the second portion 412 of at least one sub-layer 41 in the light-emitting unit 40 on the substrate 10 partially overlaps the orthogonal projection of the pixel opening 22 on the substrate 10.

It should be noted that the included angle between the virtual connection plane P3 and the thickness direction of the substrate 10 may be greater than or equal to 30° and less than or equal to 70°, for example, the included angle may be 30°, 40°, 50°, 60°, 70°, etc.

With continued reference to FIG. 5, in one embodiment, a distance from the evaporation edge P2 to the side of the pixel defining portion 21 facing away from the substrate 10 is a first distance H1, the first distance H1 satisfying: 0.5microns≤H1≤1.5 microns, in order to facilitate a rational adjustment of the included angle between the virtual connection plane P3 and the thickness direction of the substrate 10, and an orthographic projection of the second portion 412 of at least one sub-layer 41 in the light-emitting unit 40 on the substrate 10 partially overlaps an orthographic projection of the pixel opening 22 on the substrate 10.

It is noted that the first distance H1 may be greater than or equal to 0.5 microns and less than or equal to 1.5 microns, for example, the first distance H1 may be 0.5 microns, 0.6 microns, 0.7 microns, 0.8 microns, 0.9 microns, 1.2 microns, 1.3 microns, 1.4 microns, 1.5 microns, etc.

In some embodiments, the plurality of sub-layers 41 include a light-emitting functional layer 42 and a first electrode 43 stacked on a side of the light-emitting functional layer 42 facing away from the substrate 10, the first electrode 43 and the light-emitting functional layer 42 each include a first portion 411 and a second portion 412, and an included angle of the first electrode 43 is greater than or equal to an included angle of the light-emitting functional layer 42, thus by rationally setting the included angle of the first electrode 43 and the included angle of the light-emitting functional layer 42, an orthographic projection of the second portion 412 of the first electrode 43 on the substrate 10 partially overlaps an orthographic projection of the pixel opening 22 on the substrate 10, and an orthographic projection of the light-emitting functional layer 42 on the substrate 10 partially overlaps an orthographic projection of the pixel opening 22 on the substrate 10.

With continued reference to FIG. 5, in one embodiment, the included angle θ₂ of the first electrode 43 satisfies: 55°≤θ₂≤70° to rationally set the included angle of the first electrode 43. The included angle of the first electrode 43 may be greater than or equal to 55° and less than or equal to 70°, for example, the included angle of the first electrode 43 may be 55°, 60°, 62°, 65°, 67°, 70°, etc.

Referring to FIG. 6, in one embodiment, the included angle 03 of the light-emitting functional layer 42 satisfies: 30°≤θ₃≤55°, in order to rationally set the included angle of the light-emitting functional layer 42. The included angle of the light-emitting functional layer 42 may be greater than or equal to 30° and less than or equal to 55°, for example, the included angle of the light-emitting functional layer 42 may be 30°, 35°, 40°, 45°, 50°, 55°, etc.

Referring to FIG. 7, in some embodiments, a thickness reduction line P1 is formed between the first portion 411 and the second portion 412, a distance from the thickness reduction line P1 to a center of the corresponding pixel opening 22 is a second distance H2, the plurality of light-emitting units 40 include a first light-emitting unit 45, a second light-emitting unit 46 and a third light-emitting unit 47, the second distance H2 of the first light-emitting unit 45 is greater than the second distance H2 of the second light-emitting unit 46, and the second distance H2 of the second light-emitting unit 46 is greater than the second distance H2 of the third light-emitting unit 47.

Specifically, in the process of preparing the light-emitting unit 40, the first light-emitting unit 45 may be prepared before the second light-emitting unit 46, and the second light-emitting unit 46 may be prepared before the third light-emitting unit 47, that is, the first light-emitting unit 45, the second light-emitting unit 46 and the third light-emitting unit 47 are prepared in sequence.

The second distance H2 of the first light-emitting unit 45 is greater than the second distance H2 of the second light-emitting unit 46, and the second distance H2 of the second light-emitting unit 46 is greater than the second distance H2 of the third light-emitting unit 47. That is, the size of the second portion 412 of the second light-emitting unit 46 located within the pixel opening 22 is larger than the size of the second portion 412 of the first light-emitting unit 45 located within the pixel opening 22, and the size of the second portion 412 of the third light-emitting unit 47 located within the pixel opening 22 is larger than the size of the second portion 412 of the second light-emitting unit 46 located within the pixel opening 22. That is, the second portion 412 within the pixel opening 22 corresponding to the second light-emitting unit 46 is more than the second portion 412 within the pixel opening 22 corresponding to the first light-emitting unit 45, and the second portion 412 within the pixel opening 22 corresponding to the third light-emitting unit 47 is more than the second portion 412 within the pixel opening 22 corresponding to the second light-emitting unit 46, and the space occupied by the third light-emitting unit 47 outside the pixel opening 22 is smaller than the space occupied by the second light-emitting unit 46 outside the pixel opening 22, the space occupied by the second light-emitting unit 46 outside the pixel opening 22 is smaller than the space occupied by the first light-emitting unit 45 outside the pixel opening 22, and the width dimension of the pixel defining portion 21 corresponding to different light-emitting units 40 is adjusted, that is, the pixel pitch between the different light-emitting units 40 is adjusted, in order to meet the high PPI requirements of the display panel 100 on the basis of guaranteeing the performance of the display panel 100.

With continued reference to FIG. 7, in one embodiment, the isolation structure 30 includes a first isolation portion 34 and a second isolation portion 35 stacked in a direction away from the substrate 10, an orthographic projection of the first isolation portion 34 on the substrate 10 is located within an orthographic projection of the second isolation portion 35 on the substrate 10, the second isolation portion 35 includes a protruding sub-portion 351 protruding in a direction close to the isolation opening 31 with respect to the first isolation portion 34, a protruding width of the protruding sub-portion 351 corresponding to the first light-emitting unit 45 is smaller than a protruding width of the protruding sub-portion 351 corresponding to the second light-emitting unit 46, and the protruding width of the protruding sub-portion 351 corresponding to the second light-emitting unit 46 is smaller than a protruding width of the protruding sub-portion 351 corresponding to the third light-emitting unit 47, and it is possible to ensure that the second distance H2 of the first light-emitting unit 45 is greater than the second distance H2 of the second light-emitting unit 46, and that the second distance H2 of the second light-emitting unit 46 is greater than the second distance H2 of the third light-emitting unit 47, and also to reduce the requirements for an evaporation angle in the process of preparing the light-emitting unit 40, that is, the process difficulty is reduced.

With continued reference to FIG. 7, in one embodiment, the side of the second isolation portion 35 facing the isolation opening 31 forms an evaporation edge P2, a virtual connection plane P3 is connected between the thickness reduction line P1 and the evaporation edge P2, and an included angle θ₁ between the virtual connection plane P3 and the thickness direction of the substrate 10 satisfies: 30°≤θ₁≤70°, where the included angle corresponding to the first light-emitting unit 45 is less than the included angle corresponding to the second light-emitting unit 46, and the included angle corresponding to the second light-emitting unit 46 is less than the included angle corresponding to the third light-emitting unit 47, and the second distance H2 of the first light-emitting unit 40 is larger than the second distance H2 of the second light-emitting unit 46, and the second distance H2 of the second light-emitting unit 46 is greater than the second distance H2 of the third light-emitting unit 47.

In a second aspect, the present application provides a display device, including a display panel 100 according to any of the above embodiments.

In a second aspect, the present application provides a display device, including a display panel 100 according to any of the above embodiments or a display panel 100 prepared by the above-described preparation method. The display device employs all the above embodiments, and therefore has at least all the beneficial effects brought by the above embodiments, which will not be described in detail herein.

The display device may be any device with a display function, for example, a mobile device, such as a mobile phone, a tablet computer, a laptop computer, a palmtop computer, a vehicle-mounted electronic device, a wearable device, an ultra-mobile personal computer (UMPC), a netbook, or a personal digital assistant (PDA), or a non-mobile device, such as a personal computer (PC), a television (TV), a teller machine, or a self-service machine.

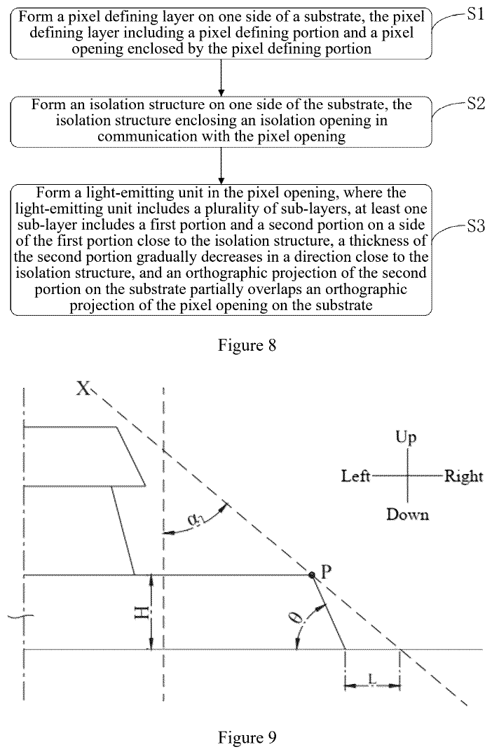

Referring to FIG. 8, a third aspect of the present application provides a method for preparing a display panel 100, the method including:
in step S1, a pixel defining layer 20 is formed on one side of a substrate 10, the pixel defining layer 20 including a pixel defining portion 21 and a pixel opening 22 enclosed by the pixel defining portion 21;
in step S2, an isolation structure 30 is formed on one side of the substrate 10, the isolation structure 30 encloses an isolation opening 31, and the isolation opening 31 is in communication with the pixel opening 22; and
in step S3, a light-emitting unit 40 is formed in the pixel opening 22, the light-emitting unit 40 including a plurality of sub-layers 41, and at least one sub-layer 41 including a first portion 411 and a second portion 412 on a side of the first portion 411 close to the isolation structure 30, where a thickness of the second portion 412 gradually decreases in a direction close to the isolation structure 30, and an orthographic projection of the second portion 412 on the substrate 10 partially overlaps an orthographic projection of the pixel opening 22 on the substrate 10.

By the preparation method of the embodiment of the present application, a pixel defining layer 20 is formed on one side of the substrate 10, the pixel defining layer 20 including a pixel defining portion 21 and a pixel opening 22 enclosed by the pixel defining portion 21, thus a light-emitting unit 40 is formed in the pixel opening 22, and it is possible to reduce carrier crosstalk in each light-emitting unit 40 to achieve a light-emitting display of the display panel 100. Also, an isolation structure 30 is formed on one side of the substrate 10, the isolation structure 30 encloses an isolation opening 31, and the isolation opening 31 is in communication with the pixel opening 22, thus, by separating the light-emitting material by the isolation structure 30, the light-emitting unit 40 may be prepared without the need for a mask, which saves on costs. Also, the light-emitting unit 40 includes a plurality of sub-layers 41, at least one sub-layer 41 includes a first portion 411 and a second portion 412 on a side of the first portion 411 close to the isolation structure 30, a thickness of the second portion 412 gradually decreases in a direction close to the isolation structure 30, an orthographic projection of the second portion 412 on the substrate 10 partially overlaps an orthographic projection of the pixel opening 22 on the substrate 10, that is, the first portion 411 and part of the second portion 412 of the sub-layer 41 are located in the pixel opening 22, and compared with the provision of a misalignment of an orthographic projection of the second portion 412 on the substrate 10 with an orthographic projection of the pixel opening 22 on the substrate 10, the space occupied by the light-emitting unit 40 outside the pixel opening 22 can be reduced, and the width dimension of the pixel defining portion 21 in the direction parallel to the substrate 10 can be correspondingly reduced, thereby reducing the pixel pitch, and thus facilitating an increase in the PPI of the display panel 100 and improving the usage performance of the display panel 100.

Referring to FIG. 9, the side of the pixel defining layer 20 near the pixel opening 22 has a ramp having a ramp angle 0, and the light-emitting functional layer 42 includes a uniform area and a thinned area, the uniform area being located in the middle of the first electrode 43, and the thinned area being located between an edge of the uniform area and an edge of the pixel defining layer 20; a length L of the thinned area satisfies a relation: L≤H (tanα−tan(π/2−θ)), where a is the evaporation angle, α and θ are acute angles, and H is the thickness of the pixel defining layer 20; L has the same unit as H; and the length L satisfies at least one of the following three: H≤15000 angstroms; α≤70°; θ≤35°.

In other cases, the pixel defining layer 20 may have a multi-layer structure, regardless of the structure of several layers, one of which satisfies the relationship between L and H.

In a first embodiment, the length L of the thinned area is set to: L≤H(tanα−tan(π/2−θ)) and H≤15000 angstroms. That is, the length L of the thinned area is set to: L≤15000 (tanα−tan(π/2−θ)), and L is measured in angstroms. In the embodiment of the present application, the blocking of evaporative cloud by an upper edge point P of the pixel defining layer 20 is reduced by reducing the thickness H of the pixel defining layer 20.

In a second embodiment, the length L of the thinned area is set to: L≤H(tanα−tan(π/2−θ) and α≤70°. That is, L≤H (tanα−tan(π/2−θ). In this embodiment, the length of the thinned area is reduced by reducing the evaporation angle a. In addition, in order to ensure that the evaporation material can completely cover the pixel defining layer 20, and to solve the problem of incomplete coverage in the pixel openings 22, the evaporation angle a is also set to be greater than or equal to 50°.

In a third embodiment, the length L of the thinned area is set to: L≤H (tanα−tan(π/2−θ)) and θ≤35°. That is, L≤H(tanα−tan(θ/2−35°)). In this embodiment, by decreasing the ramp angle θ of the pixel defining layer 20, the blocking of the evaporation material by the upper edge point P of the pixel defining layer 20 is reduced, and thus the evaporation material is deposited as evenly as possible on the first electrode 43.

Although the embodiments disclosed in the present application are as described above, the content described is only embodiments used to facilitate the understanding of the present application rather than to limit the present disclosure. The present application pertains may make any modification and variation in the form and details of embodiments without departing from the spirit and scope disclosed in the present application, but the scope of protection of the present application shall still be subject to the scope defined by the appended claims.

The above descriptions are merely specific embodiments of the present application. For convenience and brevity of description, for replacement of other connection manners described above, reference may be made to the corresponding processes in the above method embodiments, and details are not repeated herein. It should be understood that the scope of protection of the present application is not limited thereto, any equivalent modification or replacement that can be easily conceived within the technical scope disclosed in the present application in the art shall fall within the scope of protection of the present application.

1. A display panel, comprising:
a substrate;
a pixel defining layer disposed on one side of the substrate and comprising a pixel defining portion and a pixel opening enclosed by the pixel defining portion;
an isolation structure disposed on one side of the substrate and enclosing an isolation opening, the isolation opening being in communication with the pixel opening; and
a light-emitting unit disposed in the pixel opening and comprising a plurality of sub-layers, wherein at least one sub-layer comprises a first portion and a second portion on a side of the first portion close to the isolation structure, a thickness of the second portion gradually decreases in a direction close to the isolation structure, and an orthographic projection of the second portion on the substrate partially overlaps an orthographic projection of the pixel opening on the substrate.

2. The display panel according to claim 1, wherein the plurality of sub-layers comprise a light-emitting functional layer and a first electrode stacked on a side of the light-emitting functional layer facing away from the substrate, the first electrode comprising the first portion and the second portion.

3. The display panel according to claim 2, wherein the plurality of sub-layers further comprise a first carrier layer between the light-emitting functional layer and the first electrode, the first carrier layer comprising the first portion and the second portion.

4. The display panel according to claim 3, wherein the light-emitting functional layer comprises the first portion and the second portion; and
the plurality of sub-layers further comprise a second electrode and a second carrier layer between the second electrode and the light-emitting functional layer, the second carrier layer comprising the first portion and the second portion.

5. The display panel according to claim 2, wherein the isolation structure comprises a first isolation segment and a second isolation segment located on a peripheral side of the isolation opening, the first electrode being connected to the first isolation segment, wherein the first electrode is connected to the second isolation segment, or the first electrode is spaced apart from the second isolation segment.

6. The display panel according to claim 5, wherein the first electrode is spaced apart from the second isolation segment, and a distance from a side of the first isolation segment facing the isolation opening to the pixel opening is less than a distance from a side of the second isolation segment facing the corresponding isolation opening to the corresponding pixel opening.

7. The display panel according to claim 1, wherein the isolation structure comprises a first isolation portion and a second isolation portion stacked in a direction away from the substrate, and an orthographic projection of the first isolation portion on the substrate is within an orthographic projection of the second isolation portion on the substrate.

8. The display panel according to claim 7, wherein the isolation structure further comprises a third isolation portion, the third isolation portion being stacked on a side of the first isolation portion facing the substrate.

9. The display panel according to claim 7, wherein a thickness reduction line is formed between the first portion and the second portion, a side of the second isolation portion facing the isolation opening forms an evaporation edge, a virtual connection plane is connected between the thickness reduction line and the evaporation edge, and an included angle θ₁ between the virtual connection plane and a thickness direction of the substrate satisfies: 30°≤θ₁≤70°.

10. The display panel according to claim 9, wherein the plurality of sub-layers comprise a light-emitting functional layer and a first electrode stacked on a side of the light-emitting functional layer facing away from the substrate, the first electrode and the light-emitting functional layer each comprise the first portion and the second portion, and the included angle of the first electrode is greater than or equal to the included angle of the light-emitting functional layer.

11. The display panel according to claim 1, wherein a thickness reduction line is formed between the first portion and the second portion, a distance from the thickness reduction line to a center of the corresponding pixel opening is a second distance, the plurality of light-emitting units comprise a first light-emitting unit, a second light-emitting unit and a third light-emitting unit, the second distance of the first light-emitting unit is greater than the second distance of the second light-emitting unit, and the second distance of the second light-emitting unit is greater than the second distance of the third light-emitting unit.

12. The display panel according to claim 11, wherein the isolation structure comprises a first isolation portion and a second isolation portion stacked in a direction away from the substrate, an orthographic projection of the first isolation portion on the substrate is within an orthographic projection of the second isolation portion on the substrate, the second isolation portion comprises a protruding sub-portion protruding in a direction close to the isolation opening with respect to the first isolation portion, a protruding width of the protruding sub-portion corresponding to the first light-emitting unit is smaller than a protruding width of the protruding sub-portion corresponding to the second light-emitting unit, and the protruding width of the protruding sub-portion corresponding to the second light-emitting unit is smaller than a protruding width of the protruding sub-portion corresponding to the third light-emitting unit.

13. The display panel according to claim 12, wherein a side of the second isolation portion facing the isolation opening forms an evaporation edge, a virtual connection plane is connected between the thickness reduction line and the evaporation edge, and an included angle θ₁ between the virtual connection plane and a thickness direction of the substrate satisfies: 30°≤θ1≤70°, wherein the included angle corresponding to the first light-emitting unit is less than the included angle corresponding to the second light-emitting unit, and the included angle corresponding to the second light-emitting unit is less than the included angle corresponding to the third light-emitting unit.

14. The display panel according to claim 1, wherein the side of the pixel defining layer close to the pixel opening has a ramp having a ramp angle θ, and the light-emitting functional layer comprises a uniform area and a thinned area, the uniform area being located in the middle of the first electrode, and the thinned area being located between an edge of the uniform area and an edge of the pixel defining layer; a length L of the thinned area satisfies a relation: L≤H (tanα−tan(π/2−θ)), wherein a is the evaporation angle, α and θ are acute angles, and H is the thickness of the pixel defining layer; L has the same unit as H; and
the length L satisfies at least one of the following three:
H≤15000 angstroms; α≤70°; and θ≤35°.

15. The display panel according to claim 14, wherein the pixel defining layer has a multi-layer structure.

16. A display device, comprising:
a display panel, comprising:
a substrate;
a pixel defining layer disposed on one side of the substrate and comprising a pixel defining portion and a pixel opening enclosed by the pixel defining portion;
an isolation structure disposed on one side of the substrate and enclosing an isolation opening, the isolation opening being in communication with the pixel opening; and
a light-emitting unit disposed in the pixel opening and comprising a plurality of sub-layers, wherein at least one sub-layer comprises a first portion and a second portion on a side of the first portion close to the isolation structure, a thickness of the second portion gradually decreases in a direction close to the isolation structure, and an orthographic projection of the second portion on the substrate partially overlaps an orthographic projection of the pixel opening on the substrate.

17. A method for preparing a display panel, the method comprising:
forming a pixel defining layer on one side of a substrate, the pixel defining layer comprising a pixel defining portion and a pixel opening enclosed by the pixel defining portion;
forming an isolation structure on one side of the substrate, the isolation structure enclosing an isolation opening in communication with the pixel opening; and
forming a light-emitting unit in the pixel opening, wherein the light-emitting unit comprises a plurality of sub-layers, at least one of the sub-layers comprises a first portion and a second portion on a side of the first portion close to the isolation structure, a thickness of the second portion gradually decreases in a direction close to the isolation structure, and an orthographic projection of the second portion on the substrate partially overlaps an orthographic projection of the pixel opening on the substrate.

18. The method for preparing a display panel according to claim 17, wherein the plurality of sub-layers comprise a light-emitting functional layer and a first electrode stacked on a side of the light-emitting functional layer facing away from the substrate, the first electrode comprising the first portion and the second portion.

19. The method for preparing a display panel according to claim 18, wherein the plurality of sub-layers further comprise a first carrier layer between the light-emitting functional layer and the first electrode, the first carrier layer comprising the first portion and the second portion.

20. The method for preparing a display panel according to claim 19, wherein the light-emitting functional layer comprises the first portion and the second portion; and
the plurality of sub-layers further comprise a second electrode and a second carrier layer between the second electrode and the light-emitting functional layer, the second carrier layer comprising the first portion and the second portion.
